(19) United States
(12) Patent Application Publication
(10) Pub. No.: US 2025/0380601 A1
(43) Pub. Date: Dec. 11, 2025

(54) DISPLAY APPARATUS

(71) Applicant: Samsung Display Co., Ltd., Yongin-si (KR)

(72) Inventors: Kyungman Kim, Yongin-si (KR); Jinho Cho, Yongin-si (KR); Jeongho Hwang, Yongin-si (KR)

(21) Appl. No.: 19/031,517

(22) Filed: Jan. 18, 2025

(30) Foreign Application Priority Data
Jun. 11, 2024 (KR) 10-2024-0075849

(51) Int. Cl. H10K 59/80; H10K 59/35; H10K 102/00

(52) U.S. Cl. CPC H10K 59/879; H10K 59/353; H10K 2102/331

(57) ABSTRACT

Provided is a display apparatus including a display panel including a plurality of pixels, and a lens layer arranged on an upper portion of the display panel and including a plurality of lens portions, wherein the display panel includes a substrate, a display layer arranged on the substrate and including a plurality of emission layers, and an encapsulation layer arranged on the display layer, and a width of each of the plurality of lens portions is a width of each of the plurality of pixels or less.

### CROSS-REFERENCE TO RELATED APPLICATION

This application claims priority to and the benefit of Korean Patent Application No. 10-2024-0075849, filed on Jun. 11, 2024, in the Korean Intellectual Property Office, the entire disclosure of which is incorporated by reference herein.

### BACKGROUND

### 1. Field

One or more aspects of embodiments of the present disclosure relate to a display apparatus, and, for example, to a display apparatus capable of improving the visibility of images output from the display apparatus.

### 2. Description of the Related Art

Recently, electronic devices have been widely used. Electronic devices are used in one or more suitable ways or applications, such as mobile electronic devices, fixed electronic devices, and/or the like, and these electronic devices include a display apparatus capable of providing a user with visual information, such as images, videos, and/or the like, to support one or more suitable functions.

Generally, a display apparatus may be a display apparatus including an organic light-emitting diode including an intermediate layer including an emission layer arranged between two electrodes. In such an organic light-emitting display apparatus, it is generally preferred to direct light generated by the emission layer toward a user. However, light generated by the emission layer of the organic light-emitting display apparatus travels in one or more directions, so the brightness of light in front of the user is low, or less than what is possible. In addition, when the surface of the display apparatus is formed to be smooth for image visibility, due to reflection of external light, the image visibility for the user is reduced, and glare is caused.

The herein-mentioned related (e.g., background) art is technical information that the author (e.g., inventor) possesses for deriving the subject matter of the present disclosure, or obtains in the process of deriving the subject matter of the disclosure, and is not necessarily known technology disclosed to the general public prior to the filing of the present disclosure.

### SUMMARY

One or more aspects of embodiments of the present disclosure are directed toward a display apparatus capable of improving the visibility of images output from the display apparatus.

However, it should be noted that these objectives are merely examples, and the scope of the disclosure is not limited to the herein-mentioned aspects. Rather, other objectives of embodiments of the present disclosure will be apparent to those skilled in the art from the following descriptions.

Additional aspects of embodiments will be set forth in part in the description which follows and, in part, will be apparent from the description, or may be learned by practice of the presented embodiments of the disclosure.

According to one or more embodiments, a display apparatus includes a display panel including a plurality of pixels, and a lens layer arranged on an upper portion of the display panel and including a plurality of lens portions, wherein the display panel includes a substrate, a display layer arranged on the substrate and including a plurality of emission layers, and an encapsulation layer arranged on the display layer, wherein a width of each (e.g., lens portion) of the plurality of lens portions may be (e.g., equal to) at most a width of each (e.g., pixel) of the plurality of pixels (e.g., or less).

In one or more embodiments, the plurality of pixels may be arranged in parallel in a first direction in a plan view, and the plurality of lens portions may be arranged in parallel in a second direction (e.g., inclined) at a first angle from the first direction in a plan view.

In one or more embodiments, the first angle may be at least about 15° (e.g., or more) and at most about 45° (e.g., or less).

In one or more embodiments, two adjacent pixels among the plurality of pixels may be spaced and/or apart (e.g., spaced apart or separated) from each other by a distance of a first pitch, and two adjacent lens portions among the plurality of lens portions may be spaced and/or apart (e.g., spaced apart or separated) from each other by a distance of a second pitch that is less than the first pitch. In other words, a distance between two adjacent pixels selected from among the plurality of pixels is a first pitch, and a distance between two adjacent lens portions selected from among the plurality of lens portions is a second pitch, which may be less than the first pitch.

In one or more embodiments, the first pitch may be greater than the width of the (e.g., each) lens portion.

In one or more embodiments, the second pitch may be the width of the lens portion or more and may be four times or less the width of the lens portion. In other words, the second pitch may be at least equal to the width of each lens portion, and may be at most four times the width of each lens portion.

In one or more embodiments, at least two (e.g., lens portions selected from among) of the plurality of lens portions may be arranged between two adjacent pixels selected from among the plurality of pixels.

In one or more embodiments, the lens layer may include a particle including an organic material or an inorganic material.

In one or more embodiments, the particle may include a first particle and a second particle, which have different sizes, and the size of the first particle may be about 100 times or more and about 1000 times or less the size of the second particle. In other words, the particle may include a first particle and a second particle, and a size of the first particle may be different than the second particle, and at least about 100 times, and at most about 1000 times a size of the second particle.

In one or more embodiments, the lens layer may include a first portion and a second portion, the first portion including the first particle, and the second portion being arranged on an upper portion of the first portion and including the second particle.

In one or more embodiments, each (e.g., lens portion) of the plurality of lens portions may include a convex lens.

In one or more embodiments, a convex height of the (e.g., each) lens portion may be (e.g., equal to) at most the width of the pixel (e.g., or less).

In one or more embodiments, each (e.g., lens portion) of the plurality of lens portions may include a concave lens.

In one or more embodiments, a concave depth of the (e.g., each) lens portion may be (e.g., equal to) at most the width of the pixel (e.g., or less).

In one or more embodiments, the lens layer may further include a body layer supporting (e.g., configured to support) the plurality of lens portions.

In one or more embodiments, the body layer may include a first resin, and each (e.g., lens portion) of the plurality of lens portions may include a second resin that is different from the first resin.

In one or more embodiments, the body layer may include a transparent substrate, and each (e.g., lens portion) of the plurality of lens portions may include a resin.

In one or more embodiments, the lens layer may further include a cover lens portion arranged on (e.g., to cover) the plurality of lens portions and simultaneously on (e.g., to cover) a surface of the body layer, on which the plurality of lens portions is arranged, (e.g., the plurality of lens portions being on the surface of the body layer).

In one or more embodiments, a rigidity of the cover lens portion may be greater than a rigidity of each (e.g., lens portion) of the plurality of lens portions.

In one or more embodiments, the body layer may include a first body layer and a second body layer arranged on the first body layer and having a greater rigidity than a rigidity of the first body layer (e.g., a rigidity of the second body layer being greater than a rigidity of the first body layer).

It should be noted that other aspects and features of embodiments other than those precedingly described will now become apparent from the following drawings, claims, and the detailed description of the disclosure.

### BRIEF DESCRIPTION OF THE DRAWINGS

The accompanying drawings are included to provide a further understanding of the preceding and other aspects and features of embodiments of certain embodiments of the present disclosure and are incorporated in and constitute a part of this specification. The drawings illustrate example embodiments that will be more apparent from the following description taken in conjunction with the accompanying drawings. In the drawings:

FIG. 1 is a schematic perspective view of a display apparatus according to one or more embodiments;

FIG. 2 shows a light-emitting diode included in any one sub-pixel and a sub-pixel circuit connected to the light-emitting diode of a display apparatus according to one or more embodiments;

FIG. 3 is a schematic cross-sectional view of the display apparatus of FIG. 1 according to one or more embodiments, taken along a line III-III′ of FIG. 1;

FIG. 4 is a schematic cross-sectional view of a display apparatus according to one or more embodiments;

FIG. 5 is a schematic cross-sectional view of a display apparatus according to another embodiment;

FIG. 6 is a plan view illustrating the arrangement of some sub-pixels of a display apparatus according to one or more embodiments;

FIG. 7 is a schematic plan view of a lens layer according to one or more embodiments;

FIG. 8 is a schematic cross-sectional view of a lens layer according to one or more embodiments;

FIG. 9 is a schematic cross-sectional view of a lens layer according to one or more embodiments;

FIG. 10 is a schematic plan view of a lens layer according to one or more embodiments;

FIGS. 11-12 are schematic cross-sectional views each illustrating a lens layer according to one or more embodiments; and

FIGS. 13-15 are schematic cross-sectional views each illustrating a lens layer according to one or more embodiments.

### DETAILED DESCRIPTION

Reference will now be made in more detail to embodiments, examples of which are illustrated in the accompanying drawings, wherein like reference numerals refer to like elements throughout. In this regard, the present disclosure has embodiments that may have different forms and should not be construed as being limited to the descriptions set forth herein. Rather, these embodiments are provided so that this disclosure will be thorough and complete, and will fully convey the scope of the present disclosure to those skilled in the art. Accordingly, the embodiments are merely described herein, by referring to the figures, to explain aspects of example embodiments of the present description.

As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, particular embodiments will be illustrated in the drawings and described in more detail in the written description. Effects and features of the disclosure and methods of achieving the same will be apparent with reference to embodiments and drawings described herein in detail. The subject matter of the disclosure may, however, be embodied in many different forms and should not be construed as being limited to the embodiments set forth herein. These terms are only used to distinguish one element from another element. For instance, a first element discussed herein could be termed a second element without departing from the teachings of the present disclosure. Similarly, the second element could also be termed the first element.

The subject matter of the disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” and/or the like, may be used to describe one or more suitable elements, such elements should not be limited to the preceding terms.

In the following embodiments, an expression used in the singular form such as “a,” “an,” and “the” encompasses the expression of the plural, unless it has a clearly different meaning in the context.

In the following embodiments, it is to be understood that the terms such as “comprises,” “comprising,” “comprise,” “includes,” “include,” “including,” “has,” “have,” and “having” are intended to indicate the existence of the features, or elements disclosed in the disclosure, and are not intended to preclude the possibility that one or more other features or elements may exist or may be added.

It will be understood that when a layer, region, or element is referred to as being formed “on” another layer, region, or element, it can be directly or indirectly formed “on” the other layer, region, or element. For example, intervening layers, regions, or elements may be present.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Sizes of elements in the drawings may be exaggerated for convenience of explanation. Because sizes and thicknesses of components in the drawings may be arbitrarily illustrated for convenience of explanation, the following embodiments are not limited thereto.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all chemical names, technical and scientific terms, and terms defined in common dictionaries should be interpreted as having meanings consistent with the context of the related art, and should not be interpreted in an ideal or overly formal sense.

In this context, “consisting essentially of” indicates that any additional components will not materially affect the chemical, physical, optical or electrical properties of the semiconductor film.

Further, in this specification, the phrase “plan view,” indicates viewing a target portion from the top, and the phrase “on a cross-section” indicates viewing a cross-section formed by vertically cutting a target portion from the side.

### Display Apparatus

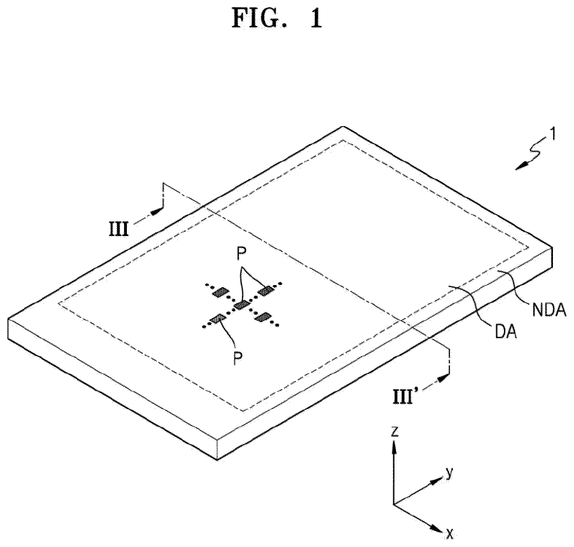

FIG. 1 is a schematic perspective view illustrating a display apparatus according to one or more embodiments.

Referring to FIG. 1, a display apparatus 1 may include a display area DA and a peripheral area NDA outside the display area DA. The display apparatus 1 may provide an image through an array of a plurality of sub-pixels P, which are two-dimensionally arranged in the display area DA.

Each of the plurality of sub-pixels P of the display apparatus 1 is an area capable of emitting a set or certain color of light, and the display apparatus 1 may provide an image by using light emitted from the plurality of sub-pixels P. For example, each of the plurality of sub-pixels P may emit red, green, blue, or white light.

Each of the plurality of sub-pixels P may emit a set or certain color of light by using a light-emitting diode, for example, an organic light-emitting diode. Each organic light-emitting diode may emit, for example, red, green, blue, or white light. Each organic light-emitting diode may be connected to a sub-pixel circuit including a thin-film transistor and a capacitor.

The peripheral area NDA is an area which does not provide an image, and may entirely surround the display area DA. A driver or a main power line, which provides an electrical signal or power to sub-pixel circuits, may be arranged in the peripheral area NDA. A pad, which is an area to which an electronic device or a printed circuit board may be electrically connected, may be arranged in the peripheral area NDA.

The display area DA may have a polygonal shape including a quadrangular shape, as shown in FIG. 1. For example, the display area DA may have a rectangular shape in which a horizontal length is greater than a vertical length, a rectangular shape in which a horizontal length is less than a vertical length, or a square shape. In some embodiments, the display area DA may have one or more suitable shapes, such as an oval shape or a circular shape.

The display apparatus 1 may include a mobile phone, a television, a billboard, a tablet personal computer (PC), a laptop, a smart watch or smart band worn on a user's wrist, and/or the like.

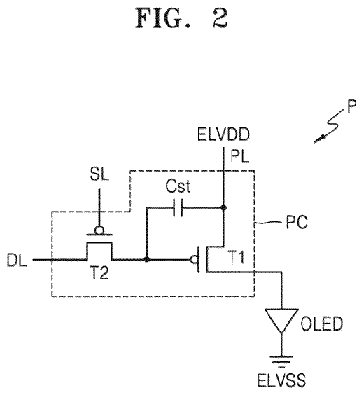

FIG. 2 shows a light-emitting diode included in any one sub-pixel and a sub-pixel circuit connected to the light-emitting diode of a display apparatus according to one or more embodiments.

Referring to FIG. 2, an organic light-emitting diode OLED is connected to a sub-pixel circuit PC as a light-emitting diode. The sub-pixel circuit PC may include a first thin-film transistor T1, a second thin-film transistor T2, and a storage capacitor Cst.

The second thin-film transistor T2 is a switching thin-film transistor, which may be connected to a scan line SL and a data line DL and be configured to transmit, to the first thin-film transistor T1, a data voltage input from the data line DL based on a switching voltage input from the scan line SL. The storage capacitor Cst may be connected to the second thin-film transistor T2 and a driving voltage line PL and store a voltage corresponding to the difference between a voltage received from the second thin-film transistor T2 and a driving voltage ELVDD supplied to the driving voltage line PL.

The first thin-film transistor T1 is a driving thin-film transistor, which may be connected to the driving voltage line PL and the storage capacitor Cst and control a driving current flowing from the driving voltage line PL through the organic light-emitting diode OLED, in accordance with a voltage value stored in the storage capacitor Cst. The organic light-emitting diode OLED may emit light having a certain brightness according to the driving current. A sub-pixel electrode (e.g., an anode) of the organic light-emitting diode OLED may be connected to the sub-pixel circuit PC. An opposite electrode (e.g., a cathode) of the organic light-emitting diode OLED may receive a common voltage ELVSS.

FIG. 2 shows that the sub-pixel circuit PC includes two thin-film transistors and one storage capacitor, but in another embodiment, the number of thin-film transistors or the number of storage capacitors may be variously changed according to the design of the sub-pixel circuit PC.

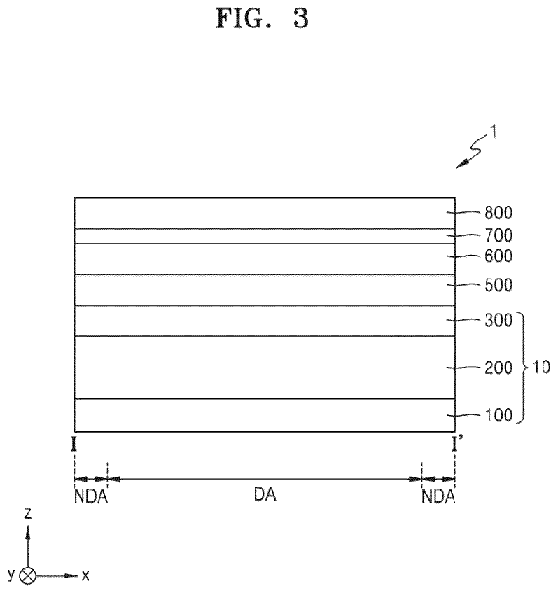

FIG. 3 is a schematic cross-sectional view of the display apparatus 1 of FIG. 1 according to one or more embodiments, taken along a line III-III′ of FIG. 1.

Referring to FIG. 3, the display apparatus 1 may include a display panel 10 and a plurality of layers arranged on an upper portion of the display panel 10. In one or more embodiments, the display panel 10 may include a substrate 100, a display layer 200, and an encapsulation layer 300. A touch sensor layer 500, a functional layer 600, a lens layer 700, and a cover window 800 may be provided on the upper portion of the display panel 10.

The substrate 100 may include glass and/or a polymer resin. For example, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. The substrate 100 including the polymer resin may be flexible, rollable, and/or bendable. The substrate 100 may have a multi-layered structure including a layer including the polymer resin and/or an inorganic layer.

The display layer 200 may include a thin-film transistor electrically connected to a light-emitting diode (e.g., an organic light-emitting diode) and insulating layers between the thin-film transistor and the light-emitting diode.

The encapsulation layer 300 may be arranged on the display layer 200. For example, the display layer 200 may be sealed with the encapsulation layer 300. The encapsulation layer 300 may include at least one inorganic encapsulation layer and at least one organic encapsulation layer.

In some embodiments, an encapsulation substrate including a glass material may also be provided instead of the encapsulation layer 300. The encapsulation substrate may be arranged on the display layer 200, and the display layer 200 may be arranged between the substrate 100 and the encapsulation substrate. A gap may exist between the encapsulation substrate and the display layer 200, and the gap may include or be filled with a filler.

The touch sensor layer 500 may be arranged on the encapsulation layer 300. The touch sensor layer 500 may detect an external input, for example, a touch of an object such as a finger and/or a stylus pen, and may allow the display apparatus 1 to obtain coordinate information corresponding to a touch position. The touch sensor layer 500 may include a touch electrode and trace lines connected to the touch electrode. The touch sensor layer 500 may sense an external input in a mutual-cap method or a self-cap method.

The touch sensor layer 500 may be directly formed on the encapsulation layer 300. In some embodiments, the touch sensor layer 500 may be separately formed and then adhered to the encapsulation layer 300 through an adhesive layer such as an optically clear adhesive.

The functional layer 600 may be arranged on the touch sensor layer 500. The functional layer 600 may improve transmittance of light emitted from the display layer 200, thereby improving the color gamut of the display apparatus 1. In some embodiments, the functional layer 600 may reduce reflectance of light incident to the display apparatus 1 from the outside, that is, external light. In one or more embodiments, the functional layer 600 may include a light-blocking layer and/or color filters. The color filters may be arranged considering a color of light emitted by each of the light-emitting diodes of the display layer 200. In another embodiment, the functional layer 600 may include a polarizing film. In this case, the functional layer 600 may include a retarder and/or a polarizer. The retarder may be a film type (e.g., kind) or a liquid-crystal coating type (e.g., kind), and may include λ/2 retarder and/or a λ/4 retarder. The polarizer may also be a film type (e.g., kind) or a liquid-crystal coating type (e.g., kind). The film-type (e.g., kind) polarizer may include a stretch-type (e.g., kind) synthetic resin film, and the liquid-crystal-coating-type (e.g., kind) polarizer may include liquid crystals in a certain arrangement. The retarder and/or the polarizer may further include a protective film.

Hereinafter, for convenience of explanation, a case in which the functional layer 600 includes a light-blocking layer and color filters is mainly described.

The lens layer 700 may be arranged on the functional layer 600. The lens layer 700 may provide or perform anti-glare by reducing reflection of light. In one or more embodiments, the lens layer 700 may include a resin and may be formed by curing the resin.

The cover window 800 may be arranged on the lens layer 700. The cover window 800 may protect the display panel 10 and the layers covering the display panel 10. The cover window 800 may be separately formed and then attached to the lens layer 700 by an adhesive layer arranged between the cover window 800 and the lens layer 700. The adhesive layer may be, for example, an optically clear adhesive. In some embodiments, the cover window 800 may also be directly formed on the lens layer 700. In some embodiments, the cover window 800 may not be provided.

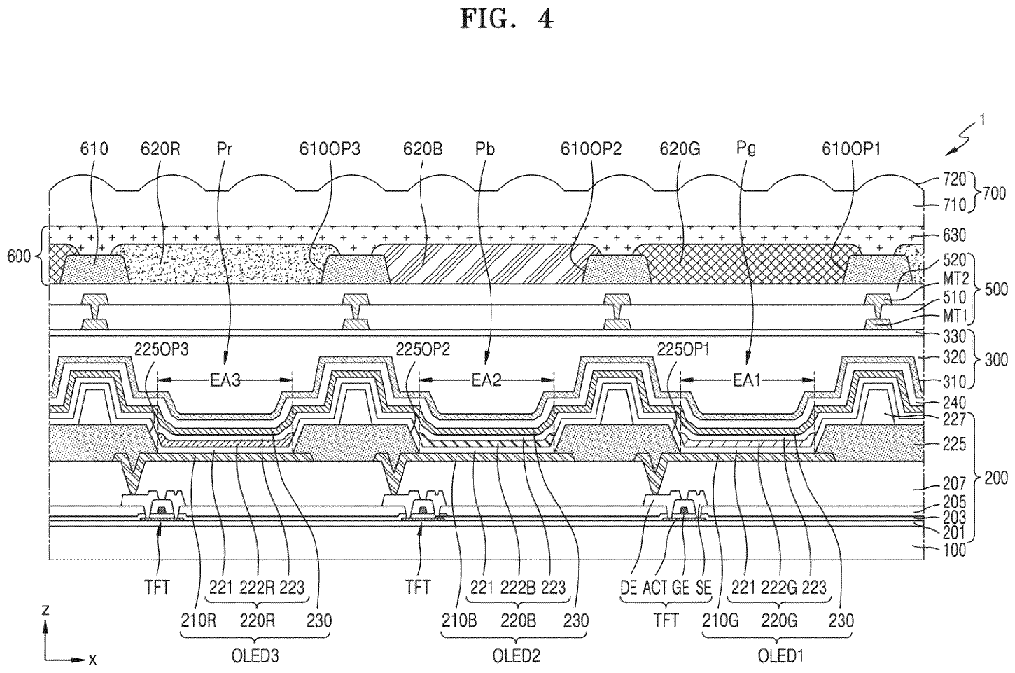

FIG. 4 is a schematic cross-sectional view of a display apparatus according to one or more embodiments.

Referring to FIG. 4, the display apparatus 1 may include the substrate 100, the display layer 200, the encapsulation layer 300, the touch sensor layer 500, the functional layer 600, the lens layer 700, and the cover window 800 (refer to FIG. 3).

The display apparatus 1 may include a plurality of sub-pixels arranged in the display area DA (refer to FIG. 3). Each of the plurality of sub-pixels may emit red, green, or blue light. The plurality of sub-pixels may include sub-pixels emitting different colors, for example, a first-color sub-pixel, a second-color sub-pixel, and a third-color sub-pixel. A plurality of first-color sub-pixels, a plurality of second-color sub-pixels, and a plurality of third-color sub-pixels may be provided. In one or more embodiments, the first-color sub-pixel may be a green sub-pixel Pg capable of emitting green light, the second-color sub-pixel may be a blue sub-pixel Pb capable of emitting blue light, and the third-color sub-pixel may be a red sub-pixel Pr capable of emitting red light.

The display layer 200 may be arranged on the substrate 100. The display layer 200 may include a sub-pixel circuit layer and a light-emitting diode layer. The sub-pixel circuit layer may include a thin-film transistor TFT and may include a buffer layer 201, a gate insulating layer 203, an interlayer insulating layer 205, and a planarization layer 207, which are insulating layers.

The buffer layer 201 may be positioned on the substrate 100 and reduce or block penetration of a foreign material, moisture, and/or external air from the lower portion of the substrate 100, and may provide a flat surface on the substrate 100. The buffer layer 201 may include an inorganic material such as an oxide or a nitride, an organic material, or a composite of an organic material and an inorganic material, and may include a single-layered structure or a multi-layered structure, each including the inorganic material and the organic material. In one or more embodiments, a barrier layer configured for blocking penetration of external air may be further included between the substrate 100 and the buffer layer 201. For example, the buffer layer 201 may include silicon oxide and/or silicon nitride.

The thin-film transistor TFT may be arranged on the buffer layer 201. The thin-film transistor TFT may include a semiconductor layer ACT, a gate electrode GE, a source electrode SE, and a drain electrode DE. The thin-film transistor TFT may be connected to an organic light-emitting diode and drive the organic light-emitting diode.

The semiconductor layer ACT may be arranged on the buffer layer 201. The semiconductor layer ACT may include polysilicon and/or amorphous silicon. In some embodiments, the semiconductor layer ACT may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel area, a source area, and/or a drain area, wherein the source area and the drain area are doped with impurities.

The gate electrode GE, the source electrode SE, and the drain electrode DE may include one or more suitable conductive materials. In one or more embodiments, the gate electrode GE may include at least one of (e.g., selected from among) molybdenum (Mo), aluminum (Al), copper (Cu), and Ti. For example, the gate electrode GE may be a single Mo layer, or may have a three-layered structure including a Mo layer, an Al layer, and the Mo layer. In one or more embodiments, each of the source electrode SE and the drain electrode DE may include at least one material selected from the group consisting of Cu, Ti, and Al. For example, each of the source electrode SE and the drain electrode DE may have a three-layered structure including a Ti layer, an Al layer, and the Ti layer.

To secure insulation between the semiconductor layer ACT and the gate electrode GE, the gate insulating layer 203 may be arranged between the gate electrode GE and the semiconductor layer ACT. The interlayer insulating layer 205 may be arranged on the upper portion of the gate electrode GE, and the source electrode SE and the drain electrode DE may be arranged on the interlayer insulating layer 205.

Each of the gate insulating layer 203 and the interlayer insulating layer 205 may include an inorganic material such as silicon oxide, silicon nitride, and/or silicon oxynitride. Each of the gate insulating layer 203 and the interlayer insulating layer 205 may be formed through, for example, chemical vapor deposition (CVD) and/or atomic layer deposition (ALD).

The planarization layer 207 may be arranged on the thin-film transistor TFT. To provide a flat upper surface, after the planarization layer 207 is formed, chemical and mechanical polishing may be performed on the upper surface of the planarization layer 207. The planarization layer 207 may include photosensitive polyimide, polyimide, polystyrene (PS), polycarbonate (PC), benzocyclobutene (BCB), hexamethyldisiloxane (HMDSO), a general commercial polymer, such as poly(methyl methacrylate) (PMMA), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and/or the like. The planarization layer 207 is shown as a single layer in FIG. 4, but in some embodiments, the planarization layer 207 may have a multi-layered structure. Sub-pixel electrodes 210G, 210B, and 210R of first to third organic light-emitting diodes OLED1, OLED2, and OLED3 may be electrically connected to the thin-film transistors TFT through contact holes of the planarization layer 207, respectively.

The light-emitting diode layer may be arranged on the sub-pixel circuit layer. In one or more embodiments, the light-emitting diode layer may include the first to third organic light-emitting diodes OLED1, OLED2, and OLED3, a bank layer 225, and a spacer 227.

The first to third organic light-emitting diodes OLED1, OLED2, and OLED3 may be arranged on the sub-pixel circuit layer. The first organic light-emitting diode OLED1 may include a stacked structure of the sub-pixel electrode 210G, an intermediate layer 220G (including a first common layer 221, an emission layer 222G, and a second common layer 223), and an opposite electrode 230. The second organic light-emitting diode OLED2 may include the sub-pixel electrode 210B, an intermediate layer 220B (including the first common layer 221, an emission layer 222B, and the second common layer 223), and the opposite electrode 230. The third organic light-emitting diode OLED3 may include the sub-pixel electrode 210R, an intermediate layer 220R (including the first common layer 221, an emission layer 222R, and the second common layer 223), and the opposite electrode 230.

The sub-pixel electrodes 210G, 210B, and 210R may be arranged on the planarization layer 207. The sub-pixel electrodes 210G, 210B, and 210R may be arranged to be spaced and/or apart (e.g., spaced apart or separated) from each other.

The sub-pixel electrodes 210G, 210B, and 210R may be reflective electrodes. Each of the sub-pixel electrodes 210G, 210B, and 210R may include a reflective film including silver (Ag), magnesium (Mg), Al, platinum (Pt), palladium (Pd), gold (Au), nickel (Ni), neodymium (Nd), iridium (Ir), Cr, or a compound thereof, and a transparent or semi-transparent conductive layer formed on the reflective film. The transparent or semi-transparent electrode layer may include at least one material selected from the group consisting of indium tin oxide (ITO), indium zinc oxide (IZO), zinc oxide (ZnO), indium oxide (In₂O₃) indium gallium oxide (IGO), and aluminum zinc oxide (AZO).

The bank layer 225 may be arranged on the sub-pixel electrodes 210G, 210B, and 210R. The bank layer 225 may have first to third lower opening portions 225OP1, 225OP2, and 225OP3 overlapping the sub-pixel electrodes 210G, 210B, and 210R and exposing the central portions of the sub-pixel electrodes 210G, 210B, and 210R, respectively. The bank layer 225 may cover the edges of the sub-pixel electrodes 210G, 210B, and 210R and prevent an arc or the like from being generated (or reduce a likelihood, occurrence, or degree of an arc being generated) at the edges of the sub-pixel electrodes 210G, 210B, and 210R by increasing the distances between the edges of the sub-pixel electrodes 210G, 210B, and 210R and the opposite electrode 230.

The first to third lower opening portions 225OP1, 225OP2, and 225OP3 of the bank layer 225 may respectively define first to third emission areas EA1, EA2, and EA3 of the first to third organic light-emitting diodes OLED1, OLED2, and OLED3 included in each pixel. As shown in FIG. 4, the bank layer 225 may include the first lower opening portion 225OP1 defining the first emission area EA1 of the first organic light-emitting diode OLED1 of the first-color sub-pixel. In some embodiments, the bank layer 225 may include the second lower opening portion 225OP2 defining the second emission area EA2 of the second organic light-emitting diode OLED2 of the second-color sub-pixel, and may include the third lower opening portion 225OP3 defining the third emission area EA3 of the third organic light-emitting diode OLED3 of the third-color sub-pixel.

The bank layer 225 may include an organic insulating material. In some embodiments, the bank layer 225 may include an inorganic insulating material, such as silicon nitride and/or silicon oxide. In some embodiments, the bank layer 225 may include an organic insulating material and/or an inorganic insulating material.

In one or more embodiments, the bank layer 225 may include a light-blocking material. For example, the light-blocking material of the bank layer 225 may be black. The light-blocking material may include carbon black, carbon nanotubes, a resin and/or paste including a black dye, metal particles, such as nickel, aluminum, molybdenum, and/or alloys thereof, metal oxide particles, metal nitride particles, and/or the like. When the bank layer 225 includes the light-blocking material, reflection of external light by metal structures arranged on the lower portion of the bank layer 225 may be reduced.

The spacer 227 may be arranged on the bank layer 225. The spacer 227 may include an organic insulating material such as PI. In some embodiments, the spacer 227 may include an inorganic insulating material, such as silicon nitride and/or silicon oxide, or may include an organic insulating material and/or an inorganic insulating material. In one or more embodiments, the spacer 227 may include a different material from the bank layer 225 including the light-blocking material described herein, and the spacer 227 and the bank layer 225 may be formed in separate processes.

In another embodiment, the spacer 227 may include the same material as the bank layer 225. In this case, the bank layer 225 and the spacer 227 may be formed together in a mask process using a halftone mask or the like.

An intermediate layer may be arranged on the sub-pixel electrodes 210G, 210B, and 210R and the bank layer 225. As described herein, the intermediate layer may include the first common layer 221, an emission layer, and the second common layer 223.

The emission layers 222G, 222B, and 222R may be respectively arranged inside the first to third lower opening portions 225OP1, 225OP2, and 225OP3 of the bank layer 225. Each of the emission layers 222G, 222B, and 222R may include an organic material including a fluorescent material and/or phosphorescent material capable of emitting green, blue, or red light. The organic material described herein may be a low-molecular-weight organic material and/or a polymer organic material.

The first common layer 221 and the second common layer 223 may be respectively arranged below and on the emission layer. The first common layer 221 may include, for example, a hole transport layer (HTL), and/or an HTL and a hole injection layer (HIL). The second common layer 223 may include, for example, an electron transport layer (ETL), and/or an ETL and an electron injection layer (EIL). In one or more embodiments, the second common layer 223 may not be provided.

While an emission layer is arranged in each sub-pixel to correspond to the first to third lower opening portions 225OP1, 225OP2, and 225OP3 of the bank layer 225, each of the first common layer 221 and the second common layer 223 may be integrally formed to entirely cover the substrate 100. In other words, each of the first common layer 221 and the second common layer 223 may be integrally formed to entirely cover the display area DA of the substrate 100. The opposite electrode 230 may be a cathode, which is an electron injection

electrode. The opposite electrode 230 may include a conductive material having a low work function. For example, the opposite electrode 230 may include a (semi) transparent layer, the (semi) transparent layer including Ag, Mg, Al, Pt, Pd, Au, Ni, Nd, Ir, Cr, lithium (Li), Ca, alloys thereof, and/or the like. In some embodiments, the opposite electrode 230 may further include a layer, such as ITO, IZO, ZnO, and/or In₂O₃, above the (semi)transparent layer including the materials stated herein.

In one or more embodiments, a capping layer 240 may be further arranged on the display layer 200. The capping layer 240 may be arranged on the first to third organic light-emitting diodes OLED1, OLED2, and OLED3. In one or more embodiments, the capping layer 240 may improve the emission efficiency of the first to third organic light-emitting diodes OLED1, OLED2, and OLED3 by the principle of constructive interference.

The capping layer 240 may be an organic capping layer including an organic material, an inorganic capping layer including an inorganic material, and/or a composite capping material including an organic material and/or an inorganic material. For example, the capping layer 240 may include a carbocyclic compound, a heterocyclic compound, an amine-group-containing compound, porphine derivatives, phthalocyanine derivatives, naphthalocyanine derivatives, an alkali metal complex, an alkali earth metal complex, or a (e.g., any suitable) combination thereof. Each of the carbocyclic compound, the heterocyclic compound, and the amine-group-containing compound may selectively be substituted with a substituent including O, N, S, Se, Si, F, Cl, Br, I, or a (e.g., any suitable) combination thereof.

The encapsulation layer 300 may be arranged on the capping layer 240. The encapsulation layer 300 may include at least one inorganic encapsulation layer and at least one organic encapsulation layer. For example, as shown in FIG. 4, the encapsulation layer 300 may include a first inorganic encapsulation layer 310, an organic encapsulation layer 320, and a second inorganic encapsulation layer 330, which are sequentially stacked.

Each of the first inorganic encapsulation layer 310 and the second inorganic encapsulation layer 330 may include an inorganic insulating material, such as silicon oxide, silicon nitride, silicon oxynitride, aluminum oxide, titanium oxide, tantalum oxide, hafnium oxide, zinc oxide, and/or the like. Each of the first inorganic encapsulation layer 310 and the second inorganic encapsulation layer 330 may have a single-layered structure or a multi-layered structure, each including the inorganic insulating material described herein.

The organic encapsulation layer 320 may relieve the internal stress of the first inorganic encapsulation layer 310 and/or the second inorganic encapsulation layer 330. The organic encapsulation layer 320 may include a polymer-based material. The organic encapsulation layer 320 may include polyethylene terephthalate, polyethylene naphthalate, PC, polyimide, polyethylene sulfonate, polyoxymethylene, polyarylate, HMDSO, an acrylic resin (for example, polymethyl methacrylate, polyacrylic acid, and/or the like), or a (e.g., any suitable) combination thereof.

The encapsulation layer 300 may have a multi-layered structure of the first inorganic encapsulation layer 310, the organic encapsulation layer 320, and the second inorganic encapsulation layer 330. In this case, even when cracks occur in the encapsulation layer 300, cracks may not propagate between the first inorganic encapsulation layer 310 and the organic encapsulation layer 320 or between the organic encapsulation layer 320 and the second inorganic encapsulation layer 330. The encapsulation layer 300 may prevent or reduce penetration of external moisture and/or oxygen to the display area DA.

The touch sensor layer 500 may be arranged on the encapsulation layer 300. The touch sensor layer 500 may include a first touch electrode MT1, a first touch insulating layer 510, a second touch electrode MT2, and/or a second touch insulating layer 520. The first touch electrode MT1 may also be arranged on the encapsulation layer 300. For example, the first touch electrode MT1 may directly be arranged on the second inorganic encapsulation layer 330 of the encapsulation layer 300. However, the disclosure is not limited thereto.

In one or more embodiments, the touch sensor layer 500 may include an insulating layer between the first touch electrode MT1 and the encapsulation layer 300. For example, the insulating layer may be arranged on the second inorganic encapsulation layer 330 of the encapsulation layer 300, e.g., to planarize a surface in which the first touch electrode MT1 and/or the like is arranged. The insulating layer may include an inorganic insulating material, such as silicon oxide, silicon nitride, silicon oxynitride, and/or the like. In some embodiments, the insulating layer may also include an organic insulating material.

The first touch insulating layer 510 may be arranged on the first touch electrode MT1. The first touch insulating layer 510 may include an inorganic material and/or an organic material. When the first touch insulating layer 510 includes an inorganic material, the first touch insulating layer 510 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the first touch insulating layer 510 includes an organic material, the first touch insulating layer 510 may include at least one material selected from the group consisting of an acrylic resin, a methacrylic resin, polyisoprene, a vinyl resin, an epoxy resin, a urethane resin, a cellulose resin, and a perylene resin.

The second touch electrode MT2 may be arranged on the first touch insulating layer 510. The second touch electrode MT2 may serve as a sensor sensing a touch input of a user. The first touch electrode MT1 may serve as a connection unit connecting the second touch electrode MT2, which is patterned, e.g., in one direction. In one or more embodiments, both of the first touch electrode MT1 and the second touch electrode MT2 may (e.g., simultaneously) serve as sensors. In this case, the first touch electrode MT1 and the second touch electrode MT2 may be electrically connected to each other through a contact hole. When both of the first touch electrode MT1 and the second touch electrode MT2 (e.g., simultaneously) serve as sensors, the resistance of the touch electrodes may be reduced, and a touch input of the user may be quickly sensed.

In one or more embodiments, each of the first touch electrode MT1 and the second touch electrode MT2 may have a structure through which light emitted from an organic light-emitting diode passes, for example, a mesh structure. For example, the first touch electrode MT1 and the second touch electrode MT2 may be arranged not to overlap the emission area EA of the organic light-emitting diode.

Each of the first touch electrode MT1 and the second touch electrode MT2 may include a metal layer or a transparent conductive layer. The metal layer may include Mo, Ag, Ti, Cu, Al, and alloys thereof. The transparent conductive layer may include a transparent conductive oxide (such as ITO, IZO, ZnO, ITZO, and/or the like), a conductive polymer such as PEDOT, a metal nanowire, a carbon nanotube or graphene, and/or the like.

The second touch insulating layer 520 may be arranged on the second touch electrode MT2. The second touch insulating layer 520 may include an inorganic material and/or an organic material. When the second touch insulating layer 520 includes an inorganic material, the second touch insulating layer 520 may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the second touch insulating layer 520 includes an organic material, the second touch insulating layer 520 may include at least one material selected from the group consisting of an acrylic resin, a methacrylic resin, polyisoprene, a vinyl resin, an epoxy resin, a urethane resin, a cellulose resin, and a perylene resin.

In some embodiments, the touch sensor layer 500 includes the first touch electrode MT1, the first touch insulating layer 510, and the second touch electrode MT2 but may not include the second touch insulating layer 520. In this case, the functional layer 600 may be provided as a structure covering (e.g., on) the second touch electrode MT2.

The functional layer 600 may be arranged on the touch sensor layer 500. Referring to FIG. 4, the functional layer 600 may include a light-blocking layer 610 and a plurality of color filters. In one or more embodiments, the functional layer 600 may include first to third color filters 620G, 620B, and 620R having different colors and respectively corresponding to the first to third organic light-emitting diodes OLED1, OLED2, and OLED3. A plurality of first color filters 620G, a plurality of second color filters 620B, and a plurality of third color filters 620R may be provided.

The light-blocking layer 610 may have first to third upper opening portions 610OP1, 610OP2, and 610OP3 respectively corresponding to the first-color sub-pixel to the third-color sub-pixel. The light-blocking layer 610 may include the first upper opening portion 610OP1 corresponding to the first emission area EA1, the second upper opening portion 610OP2 corresponding to the second emission area EA2, and the third upper opening portion 610OP3 corresponding to the third emission area EA3. Light emitted from the first to third organic light-emitting diodes OLED1, OLED2, and OLED3 may be emitted to the outside through the first to third upper opening portions 610OP1, 610OP2, and 610OP3 of the light-blocking layer 610, respectively.

The first upper opening portion 610OP1 of the light-blocking layer 610 may overlap the first lower opening portion 225OP1 of the bank layer 225, the second upper opening portion 610OP2 may overlap the second lower opening portion 225OP2, and the third upper opening portion 610OP3 may overlap the third lower opening portion 225OP3.

In one or more embodiments, the width (or size) of each sub-pixel may refer to the width (or size) of an emission area of an organic light-emitting diode implementing the each pixel, and the width (or size) of the emission area may be defined by the width (or size) of the lower opening portion provided in the bank layer 225.

In one or more embodiments, the width (or size) of each of the first to third upper opening portions 610OP1, 610OP2, and 610OP3 of the light-blocking layer 610 may be greater than the width (or size) of a corresponding sub-pixel among the first-color sub-pixel to the third-color sub-pixel. For example, the widths (or sizes) of the first to third upper opening portions 610OP1, 610OP2, and 610OP3 of the light-blocking layer 610 may be greater than the sizes (or widths) of the first to third lower opening portions 225OP1, 225OP2, and 225OP3 of a corresponding bank layer 225.

In another embodiment, the width (or size) of each of the first to third upper opening portions 610OP1, 610OP2, and 610OP3 of the light-blocking layer 610 may be substantially equal to the width (or size) of a corresponding sub-pixel of the first-color sub-pixel to the third-color sub-pixel. For example, the widths (or sizes) of the first to third upper opening portions 610OP1, 610OP2, and 610OP3 of the light-blocking layer 610 may be substantially equal to the widths (or sizes) of the first to third lower opening portions 225OP1, 225OP2, and 225OP3 of a corresponding bank layer 225.

The light-blocking layer 610 may include an organic insulating material. In some embodiments, the light-blocking layer 610 may include an inorganic insulating material, such as silicon nitride and/or silicon oxide. In some embodiments, the light-blocking layer 610 may include an organic insulating material and an inorganic insulating material.

In one or more embodiments, the light-blocking layer 610 may include a light-blocking material. For example, the light-blocking material of the light-blocking layer 610 may be black. The light-blocking material may include carbon black, carbon nanotubes, a resin and/or paste including a black dye, metal particles, such as nickel, aluminum, molybdenum, and alloys thereof, metal oxide particles, metal nitride particles, and/or the like. Because the light-blocking layer 610 includes a light-blocking material, reflection of external light by metal structures arranged on the lower portion of the light-blocking layer 610 may be reduced.

The first to third color filters 620G, 620B, and 620R may be respectively arranged in the first to third upper opening portions 610OP1, 610OP2, and 610OP3 of the light-blocking layer 610. The first to third color filters 620G, 620B, and 620R may have colors corresponding to light emitted by the first to third emission areas EA1, EA2, and EA3, respectively. In one or more embodiments, when the first emission area EA1 emits green light, the first color filter 620G may be a green color filter. When the second emission area EA2 emits blue light, the second color filter 620B may be a blue color filter. When the third emission area EA3 emits red light, the third color filter 620R may be a red color filter.

The functional layer 600 may further include an overcoat layer 630. The overcoat layer 630 may be arranged on the light-blocking layer 610 and/or the first to third color filters 620G, 620B, and 620R. The overcoat layer 630 may planarize the upper surface of the light-blocking layer 610 and/or the upper surfaces of the first to third color filters 620G, 620B, and 620R. The overcoat layer 630 is a colorless transparent layer that does not have a color of a visible light band. The overcoat layer 630 may include a colorless transparent organic material such as an acrylic resin.

The lens layer 700 may be arranged on the overcoat layer 630. The lens layer 700 may perform anti-glare by reducing reflection of light. In one or more embodiments, the lens layer 700 may include a resin and may be formed by curing the resin.

In one or more embodiments, the lens layer 700 may include a body layer 710 and a lens portion 720 convexly protruding from the body layer 710. The body layer 710 and the lens portion 720 may be integrally formed, but the disclosure is not limited thereto. The body layer 710 may be arranged on the functional layer 600, for example, the overcoat layer 630. The lens portion 720 may be formed to protrude from one surface of the body layer 710, for example, a surface thereof opposite to the overcoat layer 630. The lens layer 700 is described elsewhere herein in more detail.

In some embodiments, a cover window may be arranged on the lens layer 700. In one or more embodiments, the cover window may be attached to the lens layer 700 by an adhesive layer. In another embodiment, the cover window may not be provided.

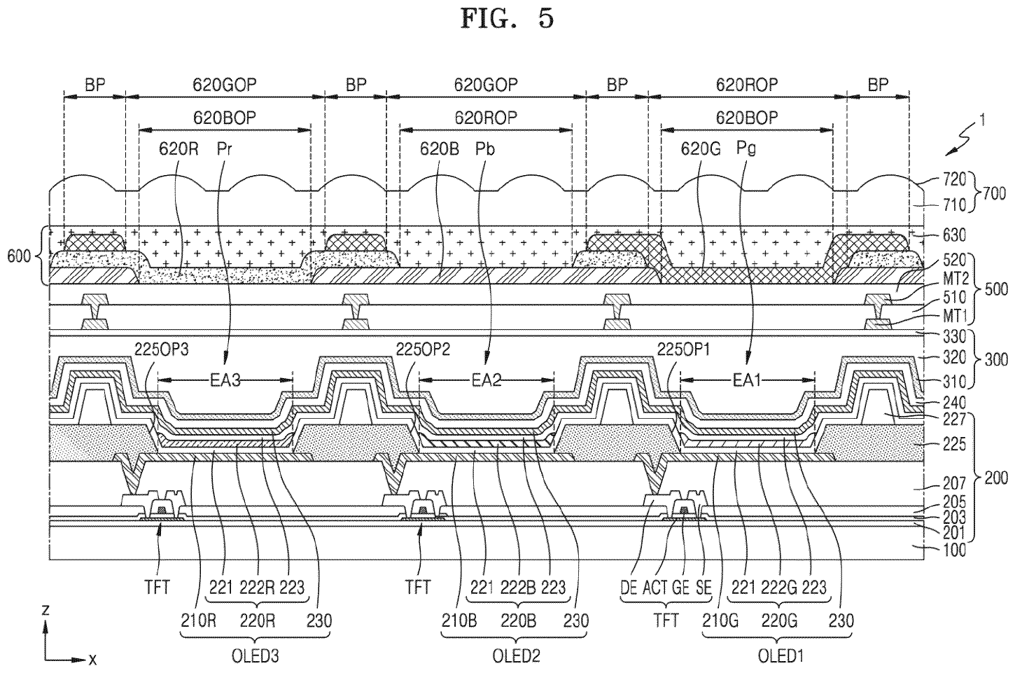

FIG. 5 is a schematic cross-sectional view of a display apparatus according to another embodiment. FIG. 5 shows a modification embodiment of the functional layer 600 of FIG. 4. Hereinafter, differences are mainly described in more detail.

Referring to FIG. 5, the functional layer 600 may not include the light-blocking layer 610 (refer to FIG. 4) and may include only a plurality of color filters.

In one or more embodiments, the second color filter 620B, the third color filter 620R, and the first color filter 620G may be sequentially stacked in a direction (+z direction) away from the substrate 100.

The second color filter 620B may allow most of the blue light to pass through and block most of the red or green light. The second color filter 620B may include second openings 620BOP corresponding to the first emission area EA1 and the third emission area EA3. The second color filter 620B may prevent red light or green light respectively emitted from the first emission area EA1 and the third emission area EA3 from being blocked by including the second openings 620BOP. Most of the blue light emitted from the second emission area EA2 may be emitted to the outside through the second color filter 620B.

The third color filter 620R may allow most of the red light to pass through and block most of the blue light or green light. The third color filter 620R may fill the second opening 620BOP corresponding to the third emission area EA3 among the second openings 620BOP of the second color filter 620B and may be arranged on the second color filter 620B. The third color filter 620R may have third openings 620ROP corresponding to the first emission area EA1 and the second emission area EA2. The third color filter 620R may prevent green light and blue light respectively emitted from the first emission area EA1 and the second emission area EA2 from being blocked by including the third openings 620ROP. Most of the red light emitted from the third emission area EA3 may be emitted to the outside through the third color filter 620R.

The first color filter 620G may allow most of the green light to pass through and block most of the red light or blue light. The first color filter 620G may fill the second opening 620BOP and the third opening 620ROP, which are corresponding to the first emission area EA1, among the second openings 620BOP of the second color filter 620B and the third openings 620ROP of the third color filter 620R and may be arranged on the third color filter 620R. The first color filter 620G may include first openings 620GOP corresponding to the second emission area EA2 and the third emission area EA3. The first color filter 620G may prevent blue light and red light respectively emitted from the second emission area EA2 and the third emission area EA3 from being blocked by including the first openings 620GOP. Most of the green light emitted from the first emission area EA1 may be emitted to the outside through the first color filter 620G.

The functional layer 600 may have light-blocking portions BP formed by sequentially stacking the first to third color filters 620G, 620B, and 620R at portions corresponding to spaces between the first to third emission areas EA1, EA2, and EA3 or spaces between the sub-pixel electrodes 210G, 210B, and 210R. The light-blocking portions BP may block light even without including the light-blocking layer 610 (refer to FIG. 4) including a black light-blocking material. In some embodiments, external light reflection of the display apparatus may also be reduced.

In one or more embodiments, the width (or size) of the third opening 620ROP of the third color filter 620R, which overlaps (e.g., is on) the first emission area EA1 of the first-color sub-pixel, may be greater than the width (or size) of the second opening 620BOP of the second color filter 620B, which overlaps (e.g., is on) the first emission area EA1 of the first-color sub-pixel. The width (or size) of the first opening 620GOP of the first color filter 620G, which overlaps (e.g., is on) the second emission area EA2 of the second-color sub-pixel, may be greater than the width (or size) of the third opening 620ROP of the third color filter 620R, which overlaps (e.g., is on) the second emission area EA2 of the second-color sub-pixel. The width (or size) of the first opening 620GOP of the first color filter 620G, which overlaps (e.g., is on) the third emission area EA3 of the third-color sub-pixel, may be greater than the width (or size) of the second opening 620BOP of the second color filter 620B, which overlaps (e.g., is on) the third emission area EA3 of the third-color sub-pixel.

Hereinafter, the description is made on the assumption that the display apparatus includes the functional layer 600 of FIG. 4, but the same structure may also be applied to the display apparatus including the functional layer 600 of FIG. 5.

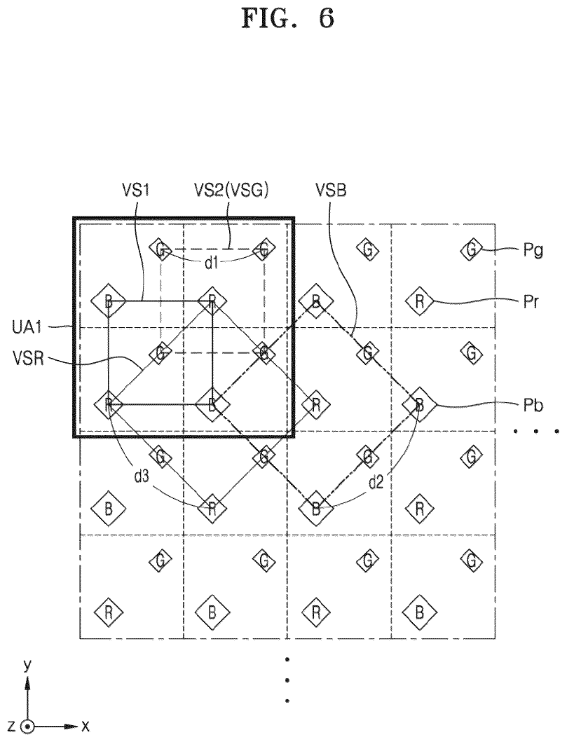

FIG. 6 is a plan view illustrating the arrangement of some sub-pixels of a display apparatus according to one or more embodiments.

Referring to FIG. 6, a plurality of sub-pixels of the display apparatus may include a first-color sub-pixel, a second-color sub-pixel, and a third-color sub-pixel. In one or more embodiments, the first-color sub-pixel may be the green sub-pixel Pg, the second-color sub-pixel may be the blue sub-pixel Pb, and the third-color sub-pixel may be the red sub-pixel Pr. Hereinafter, description is made on the assumption that the first-color sub-pixel is the green sub-pixel Pg, the second-color sub-pixel is the blue sub-pixel Pb, and the third-color sub-pixel is the red sub-pixel Pr.

The red sub-pixels Pr, the blue sub-pixels Pb, and the green sub-pixels Pg may have a repeating arrangement structure. In one or more embodiments, the red sub-pixel Pr and the blue sub-pixel Pb may be arranged at the vertices of a virtual quadrangle VS1 with any one green sub-pixel Pg as the center point. The red sub-pixel Pr may be arranged at each of opposite vertices in a diagonal direction of the virtual quadrangle VS1 with the green sub-pixel Pg therebetween. The blue sub-pixel Pb may be arranged at each of opposite vertices in a diagonal direction of the virtual quadrangle VS1 with the green sub-pixel Pg therebetween. In some embodiments, the green sub-pixels Pg may be arranged at respective vertices of a virtual quadrangle VS2 with a sub-pixel (the blue sub-pixel Pb or the red sub-pixel Pr), which may be positioned at any one vertex of the virtual quadrangle VS1, as the center point. In one or more embodiments, the virtual quadrangles VS1 and VS2 may each be a rectangle. For example, the virtual quadrangles VS1 and VS2 may each be a square.

When the arrangement of the sub-pixels of FIG. 6 is expressed differently, the red sub-pixel Pr, the blue sub-pixel Pb, and the green sub-pixel Pg may be arranged in a PENTILE® form or structure, (e.g., an RGBG matrix, an RGBG structure, or an RGBG matrix structure), for example, a DIAMOND PIXEL™ form or structure, (e.g., a display (e.g., an OLED display) containing red, blue, and green (RGB) light emitting regions arranged in the shape of diamonds. PENTILE® and DIAMOND PIXEL™ are trademarks owned by Samsung Display Co., Ltd. However, the disclosure is not limited thereto. For example, the red sub-pixel Pr, the blue sub-pixel Pb, and the green sub-pixel Pg may be arranged in a stripe structure. Hereinafter, a case in which the sub-pixels are arranged in a PENTILE® structure is mainly described in more detail.

Each of the red sub-pixel Pr, the blue sub-pixel Pb, and the green sub-pixel Pg may have a quadrangular shape. However, the disclosure is not limited thereto. In some embodiments, each of the red sub-pixel Pr, the blue sub-pixel Pb, and the green sub-pixel Pg may have an oval shape, a circular shape, or a polygonal shape. The polygonal shape may include a shape in which the vertices are rounded.

The sizes (or widths) of the red sub-pixel Pr, the blue sub-pixel Pb, and the green sub-pixel Pg may each independently be dissimilar or differently provided. For example, the size (or width) of the green sub-pixel Pg may be provided to be smaller than that of the red sub-pixel Pr and/or the blue sub-pixel Pb. The size (or width) of the blue sub-pixel Pb may be provided to be greater than the size (or width) of the red sub-pixel Pr. In another embodiment, one or more suitable modifications are possible, for example, the sizes of the red sub-pixel Pr, the blue sub-pixel Pb, and the green sub-pixel Pg may each be substantially the same.

The sub-pixels of the display apparatus may include a repeating arrangement structure of a certain sub-pixel pattern unit UA1. For example, the arrangement of the red sub-pixels Pr, the blue sub-pixels Pb, and the green sub-pixels Pg may each correspond to a repetitive arrangement of the certain sub-pixel pattern unit UA1. In the disclosure, the term “a sub-pixel pattern unit” refers to a virtual unit block with a certain area including the red sub-pixel Pr, the blue sub-pixel Pb, and the green sub-pixel Pg, which may be understood as corresponding to a minimum repeating unit of the arrangement pattern of the sub-pixels provided in the display apparatus. In one or more embodiments, the sub-pixel pattern unit UA1 may have a rectangular shape. For example, the sub-pixel pattern unit UA1 may have a square shape.

In one or more embodiments, the sub-pixel pattern unit UA1 may include the red sub-pixel Pr, the blue sub-pixel Pb, and the green sub-pixel Pg, and the sum of the numbers of red sub-pixels Pr and blue sub-pixels Pb included in the sub-pixel pattern unit UA1 may be equal to the number of green sub-pixels Pg included in the sub-pixel pattern unit UA1. For example, the number ratio of the green sub-pixel Pg, the blue sub-pixel Pb, and the red sub-pixel Pr included in the sub-pixel pattern unit UA1 may be 2:1:1. For example, FIG. 6 shows that the sub-pixel pattern unit UA1 includes four green sub-pixels Pg, two blue sub-pixels Pb, and two red sub-pixels Pr.

In the sub-pixel arrangement structure of FIG. 6, the green sub-pixels Pg adjacent to each other may be arranged at respective vertices of a virtual square VSG with the red sub-pixel Pr or the blue sub-pixel Pb as the center point. The blue sub-pixels Pb adjacent to each other may be arranged at respective vertices of a virtual square VSB with the red sub-pixel Pr as the center point. The red sub-pixels Pr adjacent to each other may be arranged at respective vertices of a virtual square VSR with the blue sub-pixel Pb as the center point. Two adjacent green sub-pixels Pg may be arranged in an x direction or a y direction. Two adjacent blue sub-pixels Pb may be arranged in a diagonal direction inclined with respect to the x direction or the y direction. Two adjacent red sub-pixels Pr may be arranged in a diagonal direction inclined with respect to the x direction or the y direction. The two adjacent blue sub-pixels Pb may be arranged in a direction inclined at 45° with respect to the x direction or the y direction. The two adjacent red sub-pixels Pr may be arranged in a direction inclined at 45° with respect to the x direction or the y direction.

In one or more embodiments, a first distance d1 between the two adjacent green sub-pixels Pg may be less than a second distance d2 between the two adjacent blue sub-pixels Pb. The first distance d1 between the two adjacent green sub-pixels Pg may be less than a third distance d3 between the two adjacent red sub-pixels Pr. The second distance d2 between the two adjacent blue sub-pixels Pb may be equal to the third distance d3 between the two adjacent red sub-pixels Pr. For example, the first distance d1 between the two adjacent green sub-pixels Pg may be (e.g., equal to) “the inverse of the square root of ‘2’” times the second distance d2 (e.g., “d2”·(2)^{-0.5}) or the third distance d3 (e.g., “d3”·(2)^{-0.5}).

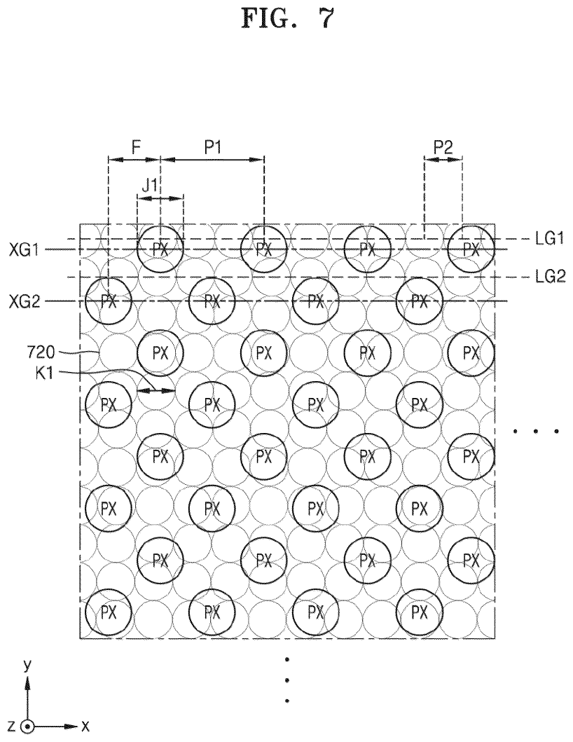

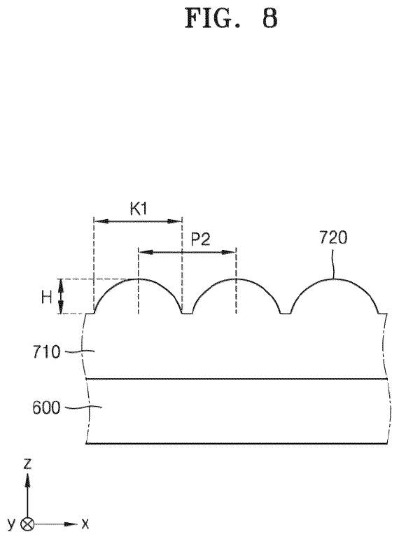

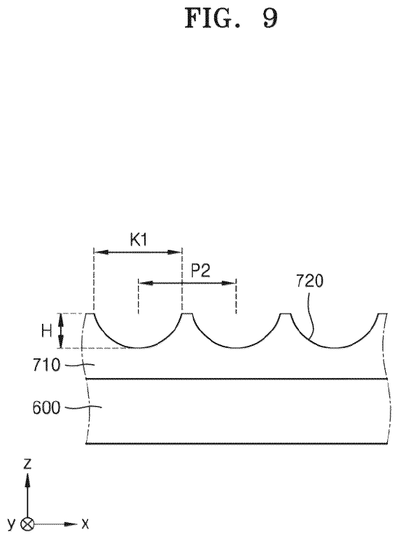

FIG. 7 is a schematic plan view of a lens layer according to one or more embodiments. FIG. 8 is a schematic cross-sectional view of a lens layer according to one or more embodiments. FIG. 9 is a schematic cross-sectional view of a lens layer according to one or more embodiments. For convenience of explanation, the sub-pixels are schematically shown in FIG. 7. In some embodiments, for convenience of explanation, the sub-pixels are expressed as pixels PX without distinguishing the emission colors of the sub-pixels, and an arrangement relationship between the pixel PX and the lens layer 700 is mainly described.

Referring to FIG. 7, the pixels PX of the display apparatus 1 may be arranged in a PENTILE® structure, for example, a Diamond Pixel™ structure, as described herein. In this case, each of the pixels PX may be defined as having a certain width J1, and the pixels PX may be arranged in parallel and spaced and/or apart (e.g., spaced apart or separated) from each other in a first direction (e.g., an x direction) and may be defined as a first pixel group XG1. In some embodiments, a second pixel group XG2 arranged to be in parallel with the first pixel group XG1 in the first direction and spaced and/or apart (e.g., spaced apart or separated) from the first pixel group XG1 in a second direction (e.g., a y direction) may be defined. Similar to the second pixel group XG2, a third pixel group and/or the like may also be defined.

The pixels PX of the first pixel group XG1 may be arranged to be spaced and/or apart (e.g., spaced apart or separated) from each other by a first pitch P1 in the first direction. In some embodiments, the pixels PX of the second pixel group XG2 may also be arranged to be spaced and/or apart (e.g., spaced apart or separated) from each other by the first pitch P1 in the first direction. For example, the second pixel group XG2 may be shifted and arranged to be offset from the first pixel group XG1 by a certain distance F. For example, the certain distance F may represent an offset distance between the center of the pixel of the first pixel group XG1 and the center of the pixel of the second pixel group XG2, which are adjacent to each other. In one or more embodiments, the certain distance F may be less than the first pitch P1, and preferably, the certain distance F may be (e.g., equal to) “½” of the first pitch P1 (e.g., 0.5·“P1”). Accordingly, when viewed from the second direction, the pixels of the second pixel group XG2 may be arranged between the pixels of the first pixel group XG1.

Referring to FIGS. 7 and 8, the lens layer 700 may be arranged on the functional layer 600, as described herein. In one or more embodiments, the lens layer 700 may include the body layer 710 and the lens portion 720. The body layer 710 and the lens portion 720 may be integrally formed, but the disclosure is not limited thereto. The body layer 710 may be arranged on the functional layer 600, for example, the overcoat layer 630. The body layer 710 may be arranged to completely cover (e.g., be on) the display area of the display apparatus.

A plurality of the lens portions 720 may be provided to be spaced and/or apart (e.g., spaced apart or separated) from each other. The lens portion 720 is a portion convexly protruding from the body layer 710, which may be a convex lens. In particular, the lens portion 720 may be formed to protrude from one surface of the body layer 710, for example, a surface thereof opposite to the overcoat layer 630. In one or more embodiments, a protrusion height H of the lens portion 720 may be at least about 0.1 μm (e.g., or more) and at most 35 μm (e.g., or less). In some embodiments, the protrusion height H of the lens portion 720 may be (e.g., equal to) at most the width J1 of the pixel PX (e.g., or less).

As shown in FIG. 9, the lens portion 720 is a portion concavely recessed in the body layer 710, which may be a concave lens. In some embodiments, the lens portion 720 may be formed to be concavely recessed in one surface of the body layer 710, for example, a surface thereof opposite to the overcoat layer 630. At this time, in one or more embodiments, a concave depth H of the lens portion 720 may be at least about 0.1 μm (e.g., or more) and at most 35 μm (e.g., or less). In some embodiments, the concave depth H of the lens portion 720 may be the width J1 of the pixel PX or less. Hereinafter, a case in which the lens portion 720 is a convex lens is described in more detail.

Referring to FIG. 7 again, the plurality of lens portions 720 may be arranged in parallel and spaced and/or apart (e.g., spaced apart or separated) from each other in the first direction (e.g., the x direction), and may be defined as a first lens group LG1. In some embodiments, a second lens group LG2 arranged to be in parallel with the first lens group LG1 in the first direction and spaced and/or apart (e.g., spaced apart or separated) from the first lens group LG1 in the second direction (e.g., the y direction) may be defined. Similar to the second lens group LG2, a third lens group and/or the like may also be defined.

The lens portions 720 of the first lens group LG1 may be arranged to be spaced and/or apart (e.g., spaced apart or separated) from each other by a second pitch P2 in the first direction. In some embodiments, the lens portions 720 of the second lens group LG2 may also be arranged to be spaced and/or apart (e.g., spaced apart or separated) from each other by the second pitch P2 in the first direction. At this time, the second lens group LG2 may be arranged to be spaced and/or apart (e.g., spaced apart or separated) from the first lens group LG1 in the second direction. For example, the second lens group LG2 may not be shifted to be offset from the first lens group LG1, and the lens portions 720 of the first lens group LG1 may be arranged in (e.g., to be) parallel with the lens portions 720 of the second lens group LG2 in a row. Accordingly, when viewed from the second direction, the lens portions 720 of the first lens group LG1 may overlap (e.g., be on) the lens portions 720 of the second lens group LG2. In some embodiments, in other words, the plurality of lens portions 720 may be said to be arranged in a grid shape.

In another embodiment, the second lens group LG2 may be shifted and arranged to be offset from the first lens group LG1 by a certain distance. For example, the certain distance represents an offset distance between the center of the lens portion of the first lens group LG1 and the center of the lens portion of the second lens group LG2, which are adjacent to each other. In one or more embodiments, the certain distance may be less than the second pitch P2, and preferably, the certain distance may be (e.g., equal to) “½” of the second pitch P2 (e.g., 0.5·“P2”). Accordingly, when viewed from the second direction, the lens portion of the second lens group LG2 may be arranged between the lens portion of the first lens group LG1. Hereinafter, a case in which the first lens group LG1 and the second lens group LG2 are not shifted to be offset, as shown in FIG. 7, is mainly described in more detail.

In one or more embodiments, the lens portion 720 may have a circular shape in a plan view. For example, in this case, the lens portion 720 may be provided in a hemispherical shape. In another embodiment, the lens portion 720 may be provided in an oval shape or a polygonal shape such as a triangular shape or a quadrangular shape in a plan view. Hereinafter, a case in which the lens portion 720 has a circular shape in a plan view is mainly described in more detail.

In one or more embodiments, a width K1 of the lens portion 720 may be at least about 0.5 μm (e.g., or more) and at most 35 μm (e.g., or less). In some embodiments, the width K1 of the lens portion 720 may be at most (e.g., equal to) the width J1 of the pixel PX (e.g., or less), and preferably, may be (e.g., equal to) “½” of the width J1 of the pixel PX (e.g., 0.5·“PX”). As such, when the width K1 of the lens portion 720 is at most (e.g., equal to) the width J1 of the pixel PX (e.g., or less), the wide angle of light emitted by the pixel PX may be changed at the lens portion 720, thereby improving the sparkle phenomenon that reduces or interferes with visibility.

In one or more embodiments, the second pitch P2 of the lens portion 720 may be at least the width K1 of the lens portion 720 (e.g., or more), and may be at most 4 times (e.g., or less) of the width K1 of the lens portion 720. In this way, as the second pitch P2 of the lens portion 720 is greater than the width K1, the surface of the lens layer 700 has more flat surface portions where the lens portion 720 is not arranged. In some embodiments, as the second pitch P2 is at most 4 times (e.g., or less) the width K1 of the lens portion 720, the lens portions 720 may be arranged in a certain number or more. Accordingly, the lens layer 700 may perform anti-glare through the lens portion 720 and improve visibility of light emitted through a flat surface portion thereof.

In one or more embodiments, the refractive index of the lens portion 720 may be at least about 1.35 (e.g., or more) and at most about 1.7 (e.g., or less), and, for example, may range from at least about 1.45 (e.g., or more) and at most about 1.55 (e.g., or less).

When viewing the arrangement of lens portion 720 and the arrangement of the pixel PX, as described herein, the plurality of pixels PX may be arranged in parallel and spaced and/or apart (e.g., spaced apart or separated) from each other in the first direction, and the plurality of lens portions 720 may also be arranged in parallel and spaced and/or apart (e.g., spaced apart or separated) from each other in the first direction. For example, the first pitch P1, which is a distance between two adjacent pixels PX among the plurality of pixels PX may be greater than the second pitch P2, which is a distance between two adjacent lens portion 720 among the plurality of lens portions 720. In some embodiments, the first pitch P1 may be greater than the width K1 of the lens portion 720. Accordingly, at least two, for example, three of the plurality of lens portions 720 may be arranged between two adjacent pixels PX among the plurality of pixels PX. Accordingly, the lens portion 720 may be arranged in an improved or optimized number and spacing by considering the arrangement of the pixel PX.

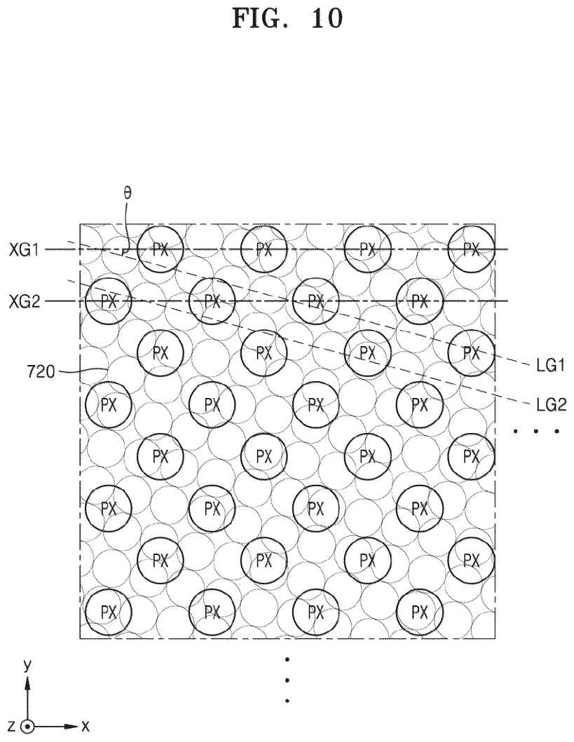

FIG. 10 is a schematic plan view of a lens layer according to one or more embodiments. The lens layer according to one or more embodiments is similar to the lens layer described herein, and thus differences thereof are mainly described in more detail herein.

Referring to FIG. 10, in one or more embodiments, the plurality of pixels PX may be arranged in parallel in the first direction (e.g., the x direction) in a plan view, and the plurality of lens portions 720 may be arranged in parallel in a second direction inclined at a first angle θ from the first direction in a plan view. For example, as described herein, each of a first pixel group XG1 and a second pixel group XG2 may be arranged in the first direction. For example, the first lens group LG1 may not be in parallel with the first pixel group XG1 but may be arranged in a direction intersecting the first pixel group PG1. For example, the first lens group LG1 may be arranged in a direction inclined at the first angle θ from the first direction, which is an extension direction of the first pixel group XG1. Because the second lens group LG2 is in parallel with the first lens group LG1, the second lens group LG2 may also be arranged in the direction at the first angle θ from the first direction. In one or more embodiments, the first angle θ may be about 15° or more and about 45° or less. Accordingly, the display apparatus 1 according to one or more embodiments may reduce or improve a moiré phenomenon.

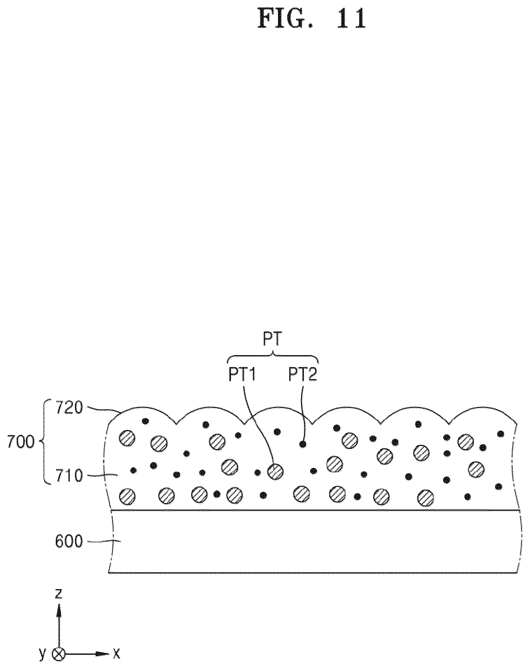

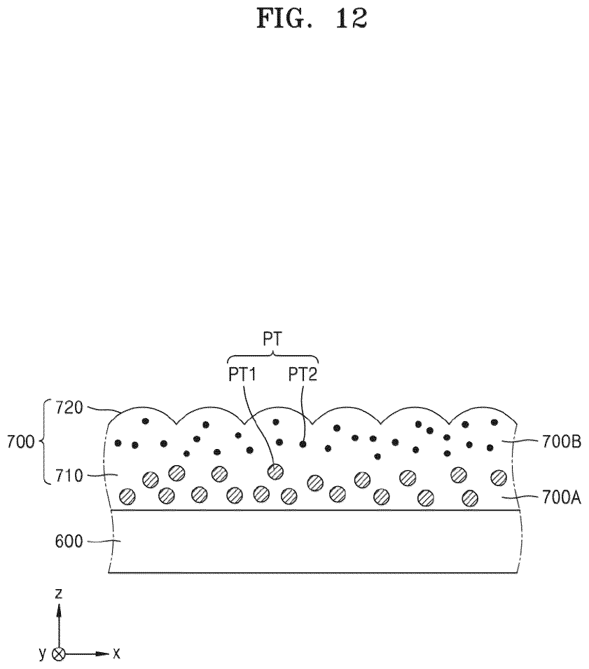

FIGS. 11-12 are schematic cross-sectional views each illustrating a lens layer according to one or more embodiments. The lens layer according to one or more embodiments is similar to the lens layer described herein, and thus differences thereof are mainly described in more detail herein.

Referring to FIG. 11, in one or more embodiments, the lens layer 700 may include a particle PT. As described herein, the lens layer 700 may include the body layer 710 and the lens portion 720, and the body layer 710 and the lens portion 720 may be integrally formed. The lens layer 700 may be formed, for example, by imprinting resin with a mold and curing the resin. At this time, the lens layer 700 may include the particle within the resin. In one or more embodiments, the particle PT may include a first particle PT1 and a second particle PT2. The first particle PT1 and the second particle PT2 may each include an organic material or an inorganic material. For example, the first particle PT1 may include an organic material, and the second particle PT2 may include an inorganic material. In some embodiments, the first particle PT1 and the second particle PT2 may both (e.g., simultaneously) include organic materials or inorganic materials.

In one or more embodiments, the first particle PT1 may have a larger particle size than that of the second particle PT2. The first particle PT1 may be, for example, at least about 1 μm (e.g., or more) and at most about 30 μm (e.g., or less). The second particle PT2 may be, for example, at least about 1 nanometer (nm) (e.g., or more) and at most about 200 nm (e.g., or less). In this case, the size of the first particle PT1 may be at least about 100 times (e.g., or more) and at most about 1000 times (e.g., or less) the size of the second particle PT2.

In one or more embodiments, the first particle PT1 and the second particle PT2 may be arranged to be dispersed throughout the lens layer 700 and mixed with each other. Because the first particle PT1 has a particle size of approximately micrometer scale, the first particle PT1 may diffract and scatter light more. Because the second particle PT2 has a particle size of approximately nanoscale, light transmittance may be further improved. Accordingly, as the first particle PT1 and the second particle PT2 are mixed with each other, the sparkle phenomenon may be improved.

Referring to FIG. 12, in another embodiment, the first particle PT1 and the second particle PT2 may be respectively arranged in different portions of the lens layer 700. In some embodiments, the lens layer 700 may include a first portion 700A and a second portion 700B. The first portion 700A is a resin layer, which may include a plurality of first particles PT1. The second portion 700B is also a resin layer, which may include a plurality of second particles PT2. The second portion 700B may be positioned on the upper portion of the first portion 700A, and accordingly, the plurality of second particles PT2 may be positioned on the upper portion of the plurality of first particles PT1. The first portion 700A and the second portion 700B may be integrally formed.

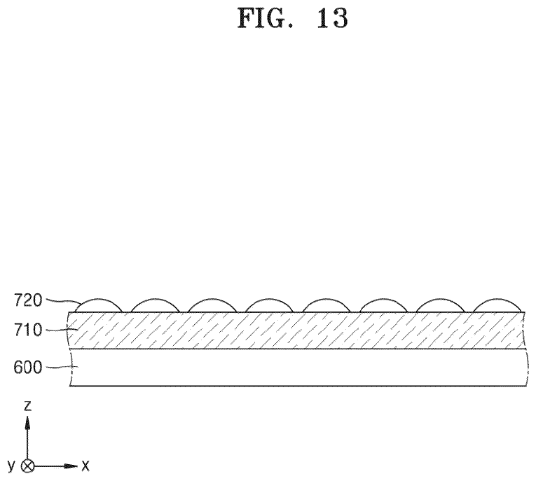

FIGS. 13-15 are schematic cross-sectional views each illustrating a lens layer according to one or more embodiments. The lens layer according to embodiments are similar to the lens layer described herein, and thus differences thereof are mainly described.

Referring to FIG. 13, in one or more embodiments, the lens layer 700 may include the body layer 710 and the lens portion 720. At this time, the body layer 710 and the lens portion 720 may be separately formed without being integrally formed. At this time, for example, the body layer 710 may include a first resin, and the lens portion 720 may include a second resin different from the first resin. In one or more embodiments, the modulus of the first resin may be greater than the modulus of the second resin. In this case, the body layer 710 including the first resin may be applied first, and the lens portion 720 including the second resin may be formed on the body layer 710.

In another embodiment, the body layer 710 may be provided as a substrate. In some embodiments, the body layer 710 may be formed as a transparent substrate and may include, for example, polyethylene terephthalate (PET). In some embodiments, the body layer 710 may include glass and may be provided in a film form. In this case, as the lens portion 720 having low rigidity is arranged on a substrate having high rigidity, appropriate rigidity may be secured while including the optical characteristics of the lens portion 720.

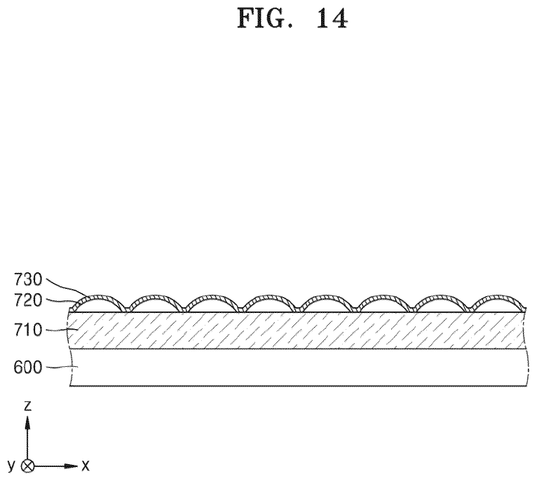

Referring to FIG. 14, as described herein, the body layer 710 may include the first resin. The lens portion 720 may be arranged on the body layer 710. At this time, in one or more embodiments, the lens portion 720 is a convex lens, which may be arranged on the body layer 710. Accordingly, similar to the embodiments described herein, the lens portion 720 may have a convex form. In some embodiments, the lens portion 720 may include the second resin different from the first resin. A cover lens portion 730 may be arranged on the lens portion 720. In one or more embodiments, the cover lens portion 730 may include a third resin different from the first resin, and the cover lens portion 730 may be arranged to cover the lens portion 720 and the upper surface of the body layer 710, on which the lens portion 720 is arranged. For example, the cover lens portion 730 may be formed by applying the third resin in a spray method. Accordingly, the cover lens portion 730 may be formed to have a plurality of convex portions corresponding to the plurality of lens portions 720, which are convex. The thickness of the cover lens portion 730 may be less than the thickness of the lens portion 720. In some embodiments, the rigidity of the cover lens portion 730 may be greater than the rigidity of the lens portion 720. Accordingly, the cover lens portion 730 may secure appropriate rigidity by supplementing the rigidity of the lens portion 720.

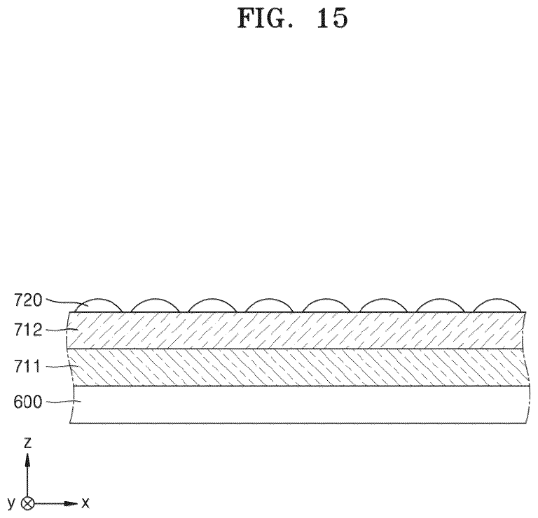

Referring to FIG. 15, in one or more embodiments, the body layer 710 may include a plurality of layers. For example, the body layer 710 may include two layers or three layers. In some embodiments, the body layer 710 may include three or more layers.

In the case where the body layer 710 includes two layers, it may be said that the body layer 710 includes a first body layer 711 and a second body layer 712. The first body layer 711 may be arranged on the upper portion of the functional layer 600, and the second body layer 712 may be arranged on the first body layer 711. In one or more embodiments, the first body layer 711 may be a resin layer including a first resin, and the second body layer 712 may be a resin layer including a second resin different from the first resin. In another embodiment, the first body layer 711 may be a resin layer including a resin, and the second body layer 712 may be provided as a transparent substrate. In another embodiment, the first body layer 711 may be provided as a transparent substrate, and the second body layer 712 may be a resin layer including a resin. In some embodiments, both of the first body layer 711 and the second body layer 712 may (e.g., simultaneously) be provided as transparent substrates.

Accordingly, embodiments of the disclosure may more easily secure required rigidity of the lens layer 700. For example, as the body layer 710 is configured by arranging a substrate (or film) with greater rigidity than a resin layer together with the resin layer, or the body layer 710 is configured by alternately arranging resin layers with different rigidities or moduli, and the rigidity of the lens layer 700 may be supplemented.

In some embodiments, a low-reflection coating layer 900 may be further arranged on the upper portion of the lens layer 700. In one or more embodiments, the low-reflection coating layer 900 may be a coating layer including a bead. For example, the bead may have a diameter of about 15 μm or more and 25 μm or less, for example, a diameter of about 20 μm. In another embodiment, the low-reflection coating layer 900 may be formed by repeatedly stacking inorganic layers including silicon oxide, silicon nitride, and titanium oxide. In this case, the low-reflection coating layer 900 may be arranged on the cover window 800 (refer to FIG. 3), or may be arranged on the lens layer 700 if the cover window 800 is absent. As such, the low-reflection coating layer 900 may function together with the lens layer 700 to prevent surface reflection of the display apparatus 1, thereby improving user visibility.

According to embodiments, glare caused by light reflection may be prevented or reduced through a lens layer, and image visibility of a display apparatus may be improved.

Effects of the disclosure are not limited to the effects mentioned herein, and other effects not mentioned will be clearly understood by one of ordinary in the art from the description of the claims.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display apparatus, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display apparatus may be formed on one integrated circuit (IC) chip or on separate IC chips. Further, the one or more suitable components of the display apparatus may be implemented on a flexible printed circuit film, a tape carrier package (TCP), a printed circuit board (PCB), or formed on one substrate. Further, the one or more suitable components of the display apparatus may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

It should be understood that one or more embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that one or more suitable changes in form and details may be made therein without departing from the spirit and scope as defined by the following claims and equivalents thereof.

1 what is claimed is:

1. A display apparatus comprising:
a display panel comprising a plurality of pixels; and
a lens layer on an upper portion of the display panel and comprising a plurality of lens portions,
wherein the display panel comprises:
a substrate,
a display layer on the substrate and comprising a plurality of emission layers, and
an encapsulation layer on the display layer, and
wherein a width of each lens portion of the plurality of lens portions is equal to at most a width of each pixel of the plurality of pixels.

2. The display apparatus of claim 1, wherein the plurality of pixels is arranged in parallel in a first direction, and
the plurality of lens portions is arranged in parallel in a second direction at a first angle from the first direction.

3. The display apparatus of claim 2, wherein the first angle is at least about 15° and at most about 45°.

4. The display apparatus of claim 1, wherein a distance between two adjacent pixels selected from among the plurality of pixels is a first pitch, and a distance between two adjacent lens portions selected from among the plurality of lens portions is a second pitch that is less than the first pitch.

5. The display apparatus of claim 4, wherein the first pitch is greater than the width of each lens portion.

6. The display apparatus of claim 4, wherein the second pitch is at least equal to the width of each lens portion and is at most four times the width of each lens portion.

7. The display apparatus of claim 1, wherein at least two lens portions selected from among the plurality of lens portions are between two adjacent pixels selected from among the plurality of pixels.

8. The display apparatus of claim 1, wherein the lens layer comprises a particle comprising an organic material or an inorganic material.

9. The display apparatus of claim 8, wherein the particle comprises a first particle and a second particle, and a size of the first particle is different than, at least about 100 times, and at most about 1000 times a size of the second particle.

10. The display apparatus of claim 9, wherein the lens layer comprises a first portion and a second portion, the first portion comprising the first particle, and the second portion on an upper portion of the first portion and comprising the second particle.

11. The display apparatus of claim 1, wherein each lens portion of the plurality of lens portions comprises a convex lens.

12. The display apparatus of claim 11, wherein a convex height of each lens portion is equal to at most the width of each pixel.

13. The display apparatus of claim 1, wherein each lens portion of the plurality of lens portions comprises a concave lens.

14. The display apparatus of claim 13, wherein a concave depth of each lens portion is equal to at most the width of each pixel.

15. The display apparatus of claim 1, wherein the lens layer further comprises a body layer configured to support the plurality of lens portions.

16. The display apparatus of claim 15, wherein the body layer comprises a first resin, and each lens portion of the plurality of lens portions comprises a second resin that is different from the first resin.

17. The display apparatus of claim 15, wherein the body layer comprises a transparent substrate, and each lens portion of the plurality of lens portions comprises a resin.

18. The display apparatus of claim 15, wherein the lens layer further comprises a cover lens portion on the plurality of lens portions and simultaneously on a surface of the body layer, the plurality of lens portions being on the surface of the body layer.

19. The display apparatus of claim 18, wherein a rigidity of the cover lens portion is greater than a rigidity of each lens portion of the plurality of lens portions.

20. The display apparatus of claim 15, wherein the body layer comprises a first body layer and a second body layer on the first body layer, a rigidity of the second body layer being greater than a rigidity of the first body layer.

21. An electronic device comprising:
a display apparatus comprising:
a display panel comprising a plurality of pixels; and
a lens layer on an upper portion of the display panel and comprising a plurality of lens portions,
wherein the display panel comprises:
a substrate,
a display layer on the substrate and comprising a plurality of emission layers, and
an encapsulation layer on the display layer, and
wherein a width of each lens portion of the plurality of lens portions is equal to at most a width of each pixel of the plurality of pixels.

22. The electronic device of claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
